(19) United States
(12) Patent Application Publication
(10) Pub. No.: US 2013/0299774 A1
(43) Pub. Date: Nov. 14, 2013

(54) LIGHT-EMITTING DIODE DEVICE AND A METHOD OF MANUFACTURING THE SAME

(71) Applicants: Yi-An Lu, Chiayi City (TW); Jinn Kong Sheu, Tainan City (TW); Ya-Hsuan Shih, Changhua County (TW)

(72) Inventors: Yi-An Lu, Chiayi City (TW); Jinn Kong Sheu, Tainan City (TW); Ya-Hsuan Shih, Changhua County (TW)

(73) Assignee: PHOSTEK, INC., HSINCHU CITY (TW)

(21) Appl. No.: 13/618,113

(22) Filed: Sep. 14, 2012

(30) Foreign Application Priority Data
May 8, 2012 (TW) 101116416

(51) Int. Cl. H01L 33/04

(52) U.S. Cl. 257/13; 257/E33.008

(57) ABSTRACT

A light-emitting diode (LED) device includes at least one LED unit, each including a substrate; an electrical coupling layer deposited above the substrate; a parallel-connected epitaxial structure deposited above the electrical coupling layer; and an intermediate layer deposited between the electrical coupling layer and the parallel-connected epitaxial structure. In another embodiment, the parallel-connected epitaxial structure is deposited above a conductive layer; the electrical coupling layer is deposited above the parallel-connected epitaxial structure; and the intermediate layer is deposited between the parallel-connected epitaxial structure and the electrical coupling layer.

### CROSS-REFERENCES TO RELATED APPLICATION

The present invention claims under 35 U.S.C. §119(a) the benefit of Taiwan Patent Application No. 101116416, filed on May 8, 2012, the entire content of which is incorporated herein by reference.

### BACKGROUND OF THE INVENTION

1. Field of the Invention

The present invention generally relates to a light-emitting diode (LED), and more particularly to a stacked LED device and a method of manufacturing the same.

2. Description of Related Art

One common technique of increasing the luminescence efficiency of a light-emitting diode (LED) is to use a tunnel junction to stack two or more LEDs. The stacked LEDs emit more light and are brighter than a single LED. The tunnel junction also enhances current spreading, which allows more carriers to perform recombination. Further, the stacked LEDs have fewer electrodes than individual LEDs yielding the same amount of light, therefore saving space and reducing electromigration associated with the electrodes.

One conventional method of forming the tunnel junction is to employ a heavy doping technique, for example, as disclosed in U.S. Pat. No. 6,822,991 entitled “Light Emitting Devices Including Tunnel Junctions,” in which indium gallium nitride (InGaN) is used in the tunnel junction. An InGaN tunnel junction should be less than 2 nanometers in thickness to achieve required quality. As disclosed in the US patent mentioned above, a p++ heavy doped InGaN tunnel junction has a thickness of 15 nanometers. It is inconceivable to attain the expected quality by using the InGaN tunnel junction with a thickness of 15 nanometers. Accordingly, it is a current trend in research and development to reduce the thickness of the InGaN tunnel junction while maintaining its tunneling effect.

Another conventional method for forming a tunnel junction is to employ a polarization technique, for example, as is disclosed in U.S. Pat. No. 6,878,975 entitled “Polarization Field Enhanced Tunnel Structures.” A tunnel junction (e.g., a single InGaN layer) made via polarization requires a high indium concentration (e.g., higher than 20%) and a significant thickness (e.g., greater than 10 nanometers), and this technique has a disadvantage of absorbing light. Moreover, as stress usually concentrates in an interface (e.g., GaN/InGaN interface) and the stress increases in proportion to temperature, a top LED of the stacked LEDs should be formed at a temperature low enough in order to not incur stress to defeat the tunneling effect.

A need has thus arisen for a novel LED structure to alleviate the problems mentioned above.

### SUMMARY OF THE INVENTION

According to one embodiment, an LED device includes at least one LED unit, each including a substrate, an electrical coupling layer, an intermediate layer, and a parallel-connected epitaxial structure. The electrical coupling layer, including group III nitride, is deposited above the substrate; the parallel-connected epitaxial structure is deposited above the electrical coupling layer; and the intermediate layer is deposited between the electrical coupling layer and the parallel-connected epitaxial structure.

According to another embodiment, an LED device includes at least one LED unit, each including a conductive layer, a parallel-connected epitaxial structure, an intermediate layer, and an electrical coupling layer. The parallel-connected epitaxial structure is deposited above the conductive layer; the electrical coupling layer is deposited above the parallel-connected epitaxial structure; and the intermediate layer is deposited between the parallel-connected epitaxial structure and the electrical coupling layer.

### BRIEF DESCRIPTION OF THE DRAWINGS

FIG. 1A to FIG. 1E show cross sections of a light-emitting diode (LED) device according to a first embodiment of the present invention;

FIG. 2 shows an equivalent circuit diagram of the parallel-connected epitaxial structure of FIG. 1B;

FIG. 3A to FIG. 3E show cross sections of an LED device according to a second embodiment of the present invention;

FIG. 4A shows a cross section of a serial-connected LED device according to a third embodiment of the present invention;

FIG. 4B shows a cross section of another serial-connected LED device according to the third embodiment of the present invention;

FIG. 5 shows an equivalent circuit diagram of the serial-connected epitaxial structure of FIG. 4A;

FIG. 6A shows a cross section of a serial-connected LED device according to a fourth embodiment of the present invention;

FIG. 6B shows a cross section of another serial-connected LED device according to the fourth embodiment of the present invention.

### DETAILED DESCRIPTION OF THE INVENTION

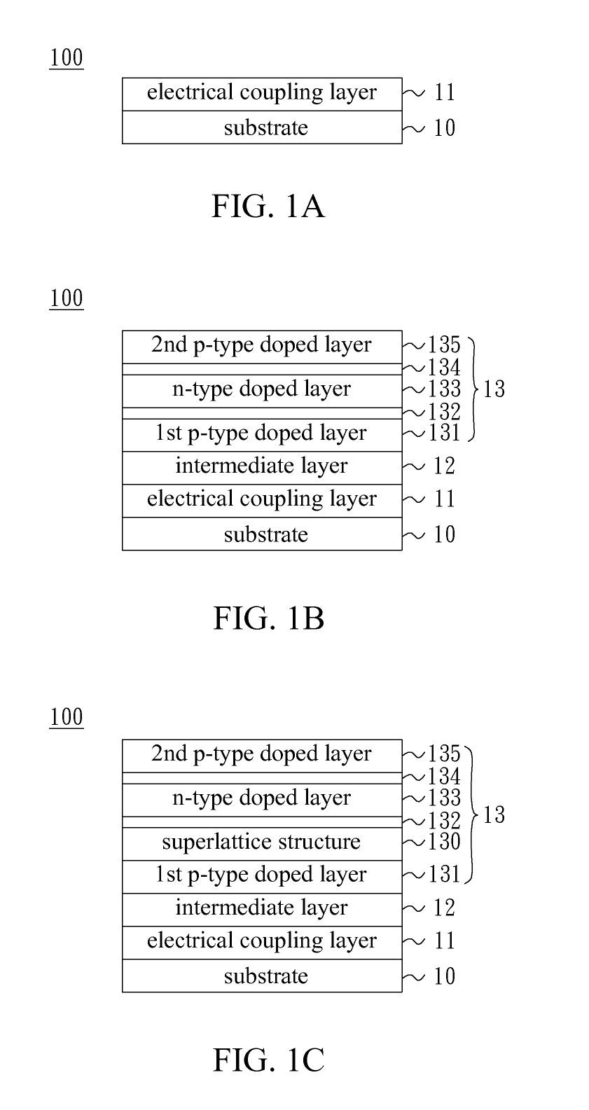

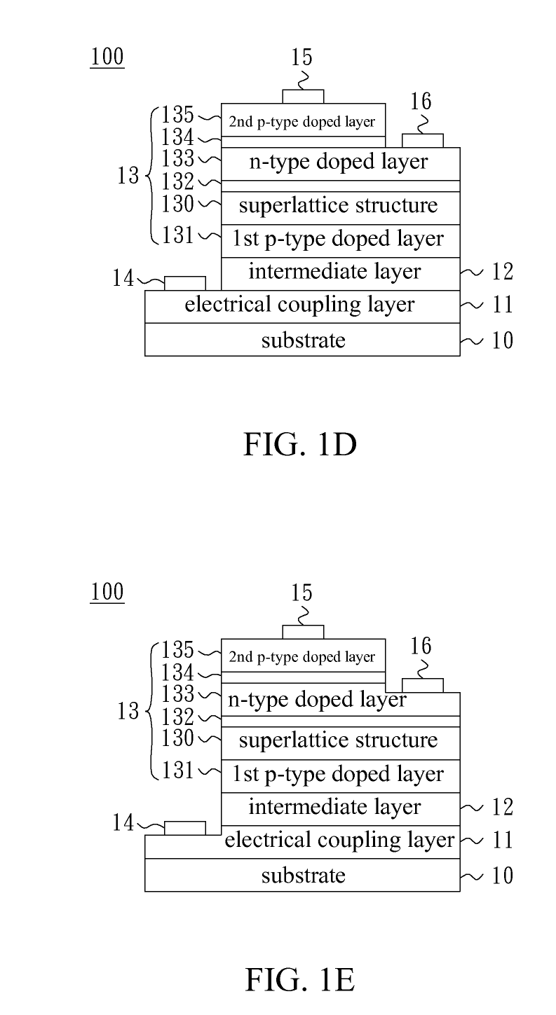

FIG. 1A to FIG. 1E show cross sections of a light-emitting diode (LED) device that includes at least one LED unit 100 according to a first embodiment of the present invention. For a clearer understanding of the embodiment, only elements pertinent to the embodiment are shown.

As shown in FIG. 1A, a substrate 10 is first provided. In the embodiment, the substrate 10 may include sapphire as the substrate material. The substrate 10 may, however, employ materials such as gallium arsenic (GaAs), germanium with silicon germanium (SiGe) formed thereon, silicon with silicon carbide (SiC) formed thereon, aluminum with aluminum oxide (Al₂O₃) formed thereon, gallium nitride (GaN), indium nitride (InN), aluminum nitride (AlN), glass, or quartz.

Referring to FIG. 1A, an electrical coupling layer 11 is formed above the substrate 10. In the embodiment, the electrical coupling layer 11 is n-type doped, and includes a group III nitride material, such as gallium nitride (GaN). According to one aspect of the embodiment, the electrical coupling layer 11 is used to enhance the quantum well of an LED element that will be formed later on, therefore increasing overall luminance efficiency of the LED unit 100.

As shown in FIG. 1B, an intermediate layer 12 is epitaxially formed above the electrical coupling layer 11. In one embodiment, the intermediate layer 12 includes a tunnel layer, for example, having a material of indium gallium nitride (InGaN). The tunnel layer may be formed by using conventional heavy doping technique or polarization technique. In another embodiment, the intermediate layer 12 may include an ohmic contact layer that is formed by using conventional heavy doping technique.

In FIG. 1B, a parallel-connected epitaxial structure 13 is formed above the intermediate layer 12. In the embodiment, the parallel-connected epitaxial structure 13 includes: a first p-type doped layer 131 formed above the intermediate layer 12; a first quantum-well layer 132 formed above the first p-type doped layer 131; an n-type doped layer 133 formed above the first quantum-well layer 132; a second quantum-well layer 134 formed above the n-type doped layer 133; and a second p-type doped layer 135 formed above the second quantum-well layer 134. In the embodiment, the first p-type doped layer 131, the n-type doped layer 133, and the second p-type doped layer 135 may include a material of group III nitride such as gallium nitride (GaN).

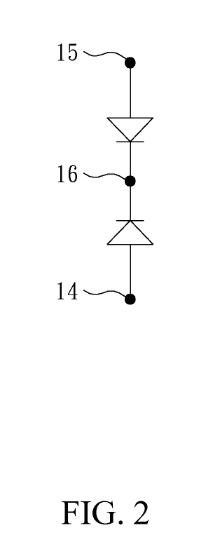

The parallel-connected epitaxial structure 13 of the embodiment forms a PNP LED unit, which may be represented by an equivalent circuit diagram shown in FIG. 2. Specifically, the first p-type doped layer 131, the first quantum-well layer 132, and the n-type doped layer 133 form a PN LED; and the second p-type doped layer 135, the second quantum-well layer 134, and the n-type doped layer 133 form another PN LED. The two PN LEDs share the n-type doped layer 133. According to another aspect of the embodiment, the intermediate layer 12 causes a voltage drop between the electrical coupling layer 11 and the first p-type doped layer 131 to approach zero volts.

FIG. 1C shows a modified embodiment of FIG. 1B. In the modified embodiment, a superlattice structure 130 is further formed between the first p-type doped layer 131 and the first quantum-well layer 132 to enhance the first quantum-well layer 132. The superlattice structure 130 may include at least two sub-layers of distinct materials (e.g., GaN and InGaN) that are stacked alternately.

The structure of FIG. 1C is subjected to an etching process to expose a partial surface of the electrical coupling layer 11 and a partial surface of the n-type doped layer 133, therefore resulting in a structure shown in FIG. 1D. In the embodiment, the inductively coupled plasma (ICP) technique is employed to perform the etching process. The etching process stops at the surface of the electrical coupling layer 11 and the surface of the n-type doped layer 133.

FIG. 1E shows a modified embedment of FIG. 1D. In the modified embodiment, a specific depth near a surface of the electrical coupling layer 11 and a surface of the n-type doped layer 133 is removed by the etching process.

Subsequently, a first electrode 14 is formed on the exposed surface of the electrical coupling layer 11, and a second electrode 15 is formed on a surface of the second p-type doped layer 135. The first electrode 14 and the second electrode 15 act as two terminal electrodes of the parallel-connected epitaxial structure 13 (i.e., the PNP LED unit). Further, a third electrode 16 is formed on the exposed surface of the n-type doped layer 133 to act as a middle electrode of the parallel-connected epitaxial structure 13 (i.e., the PNP LED unit). According to a further aspect of the embodiment, the electrical coupling layer 11 is used to electrically couple the first electrode 14 and the first p-type doped layer 131.

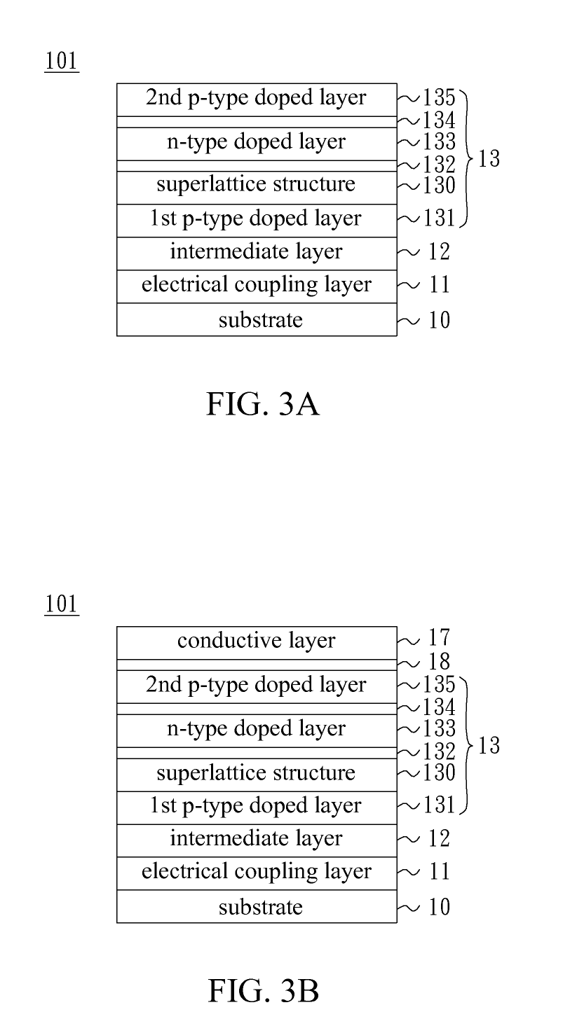

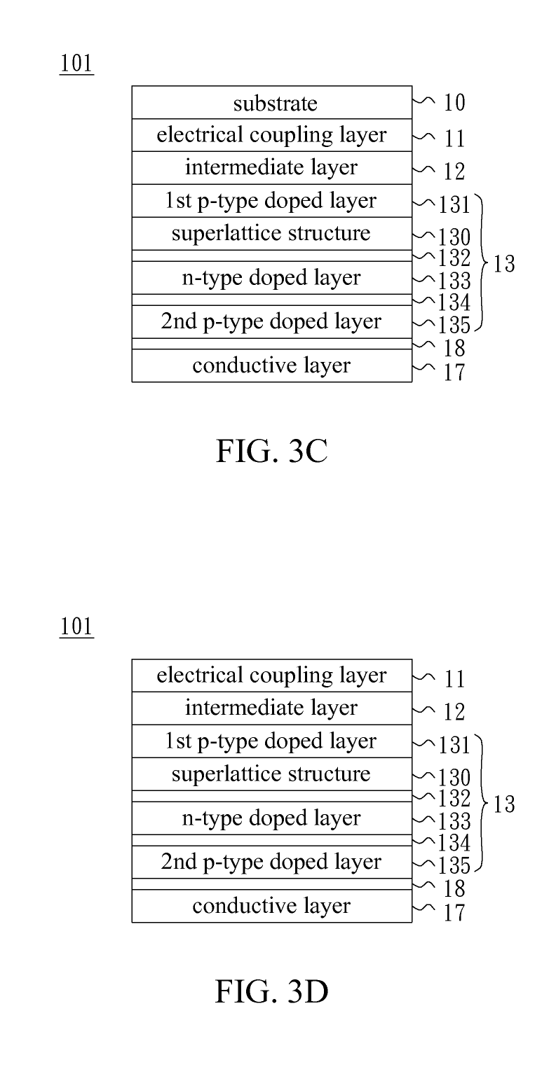

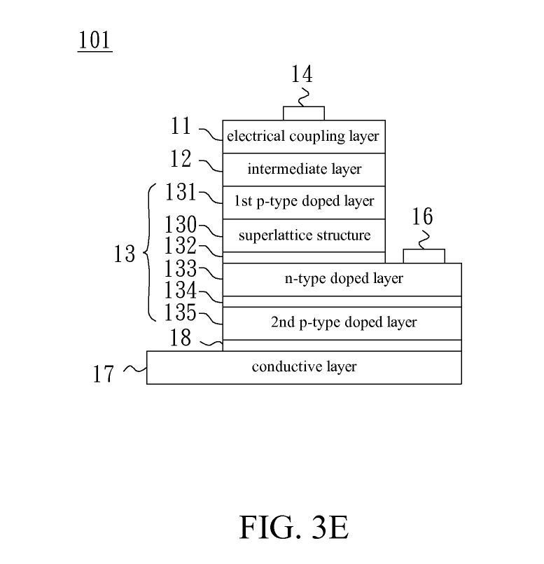

FIG. 3A to FIG. 3E show cross sections of an LED device that includes at least one LED unit 101 according to a second embodiment of the present invention. For clarity, only elements pertinent to the embodiment are shown.

A structure as shown in FIG. 3A is first formed. The structure of FIG. 3A is the same as that of FIG. 1C, and details of its formation are thus omitted. Subsequently, as shown in FIG. 3B, a conductive layer 17 is formed above the second p-type doped layer 135 of the parallel-connected epitaxial structure 13. The conductive layer 17 of the embodiment may include a material of metal. In the embodiment, the conductive layer 17 may be formed by using metal bond technique or electroplating technique. In one embodiment, a mirror layer 18 may be further formed between the conductive layer 17 and the second p-type doped layer 135 of the parallel-connected epitaxial structure 13. The mirror layer 18 may include a distributed Bragg reflector (DBR), an omnidirectional reflector (ODR), silver, aluminum, titanium, and/or other mirror conductive material.

The structure of FIG. 3B is turned over such that the conductive layer 17 is at the bottom and the substrate 10 is at the top as shown in FIG. 3C. The conductive layer 17 thereafter acts as a conductive substrate.

The substrate 10 at the top is then removed to expose the electrical coupling layer 11 as shown in FIG. 3D. In the embodiment, the substrate 10 may be removed, for example, by using laser techniques. The exposed electrical coupling layer 11 may be further subjected to etching, for instance, wet etching, to roughen its surface.

The structure of FIG. 3D is subjected to the etching process to expose a partial surface of the n-type doped layer 133, therefore resulting in a structure shown in FIG. 3E. In the embodiment, inductively coupled plasma (ICP) techniques are employed to perform the etching process. Further etching may be performed to expose a partial surface of the conductive layer 17.

Subsequently, a first electrode 14 is formed on the exposed surface of the electrical coupling layer 11. Accordingly, the first electrode 14 and the conductive layer 17 act as two terminal electrodes of the parallel-connected epitaxial structure 13 (i.e., the PNP LED unit). Further, a third electrode 16 is formed on the exposed surface of the n-type doped layer 133 to act as a middle electrode of the parallel-connected epitaxial structure 13 (i.e., the PNP LED unit).

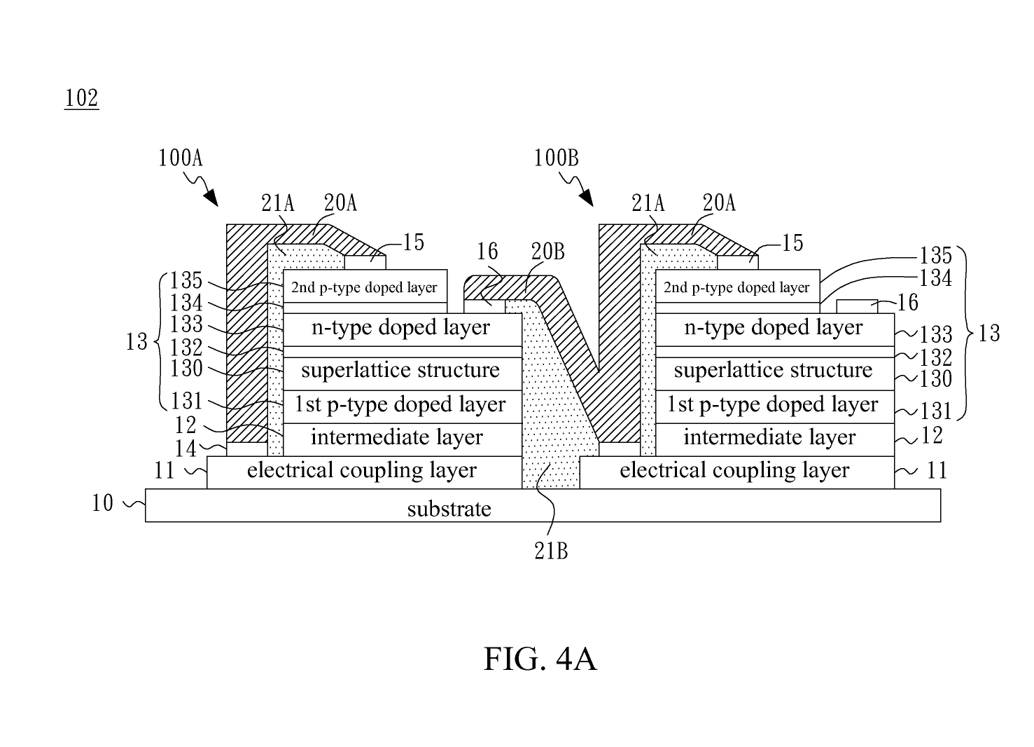

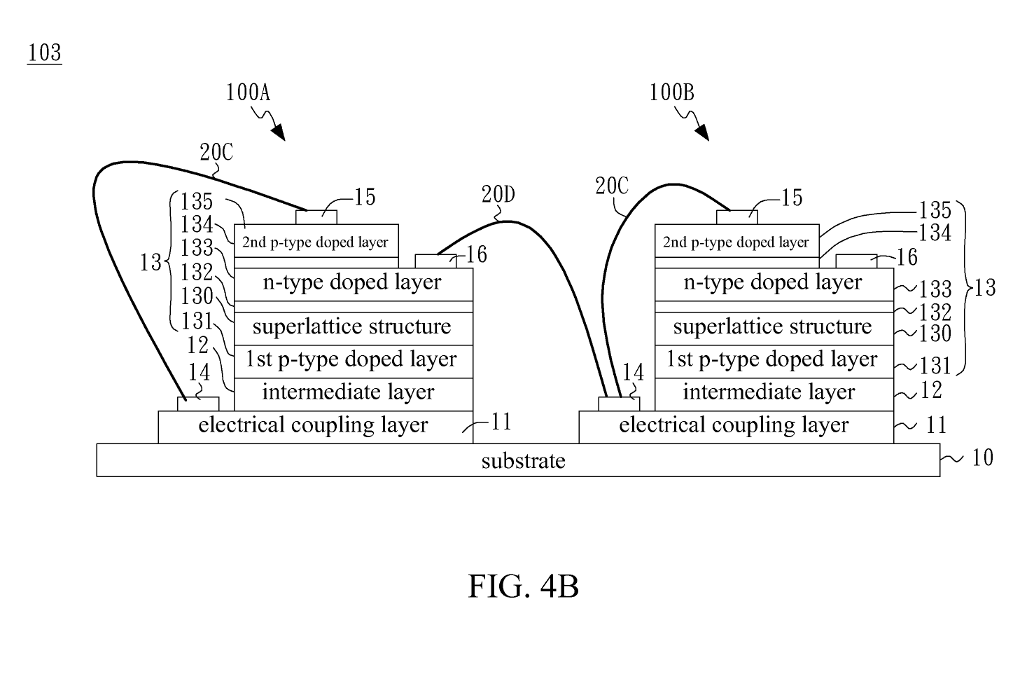

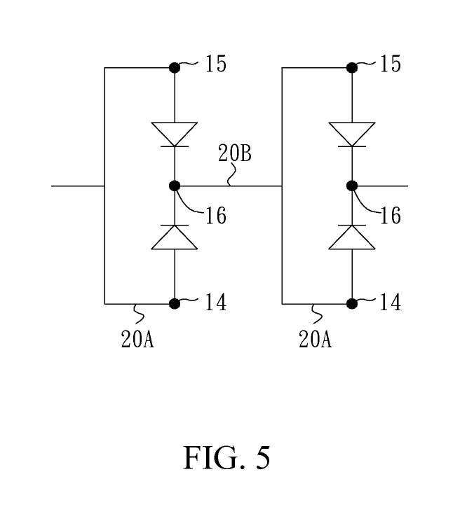

FIG. 4A shows a cross section of an LED device 102 that includes serial-connected LED units 100 of FIG. 1D according to a third embodiment of the present invention. As exemplified in FIG. 4A, a first LED unit 100A and a second LED unit 100B are serial-connected, and are fixed on a common substrate 10, such as a sapphire substrate. In one exemplary embodiment, the LED units 100A and 100B are epitaxially formed on the common substrate 10. The first electrode 14 is electrically connected with the second electrode 15 via a first interconnect 20A, and the third electrode 16 of the first LED unit 100A is electrically connected with the first electrode 14 of the second LED unit 100B via a second interconnect 20B. The first interconnect 20A is insulated from the first/second LED unit 100A/100B by a first insulating layer 21A to prevent unwanted shorting. The second interconnect 20B is insulated from the first LED unit 100A and from the second LED unit 100B by a second insulating layer 21B to prevent unwanted shorting. The serial-connected LED device 102 may be represented by an equivalent circuit diagram as shown in FIG. 5, which includes serial-connected PNP LED units.

FIG. 4B shows a cross section of another LED device 103 according to the third embodiment of the present invention. The present embodiment is similar to FIG. 4A with the exception that a first bonding wire 20C and a second bonding wire 20D are used to replace the first interconnect 20A and the second interconnect 20B, respectively.

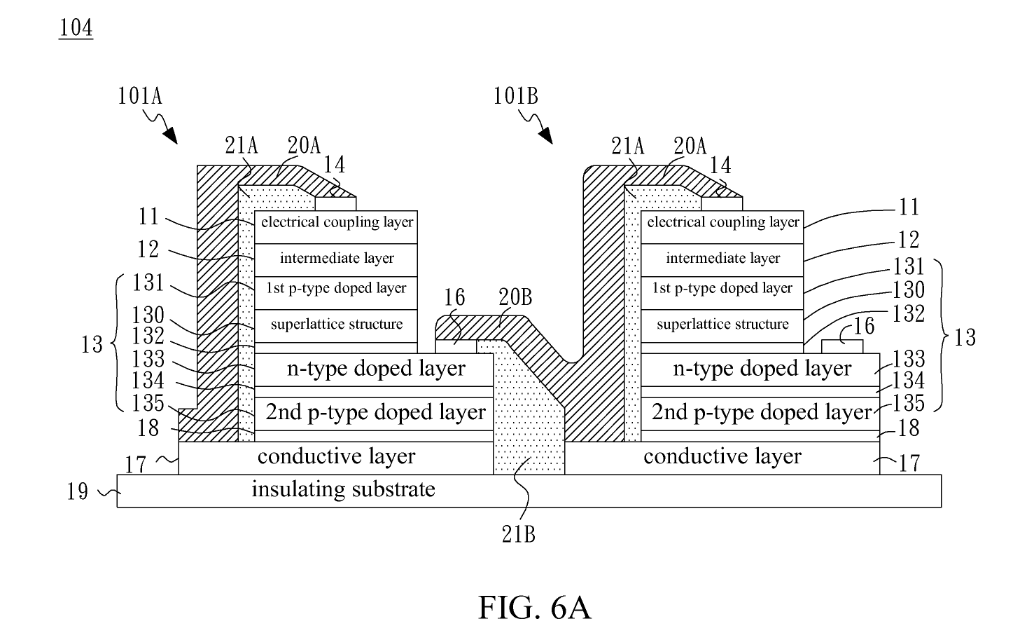

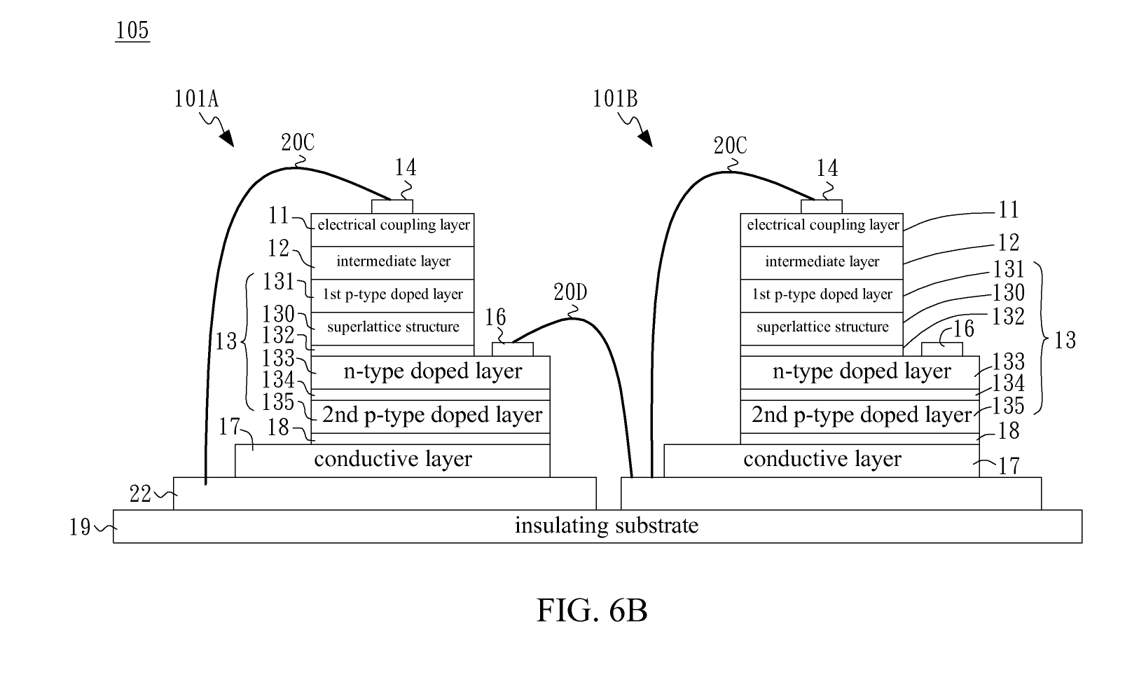

FIG. 6A shows a cross section of an LED device 104 that includes serial-connected LED units 101 of FIG. 3E according to a fourth embodiment of the present invention. As exemplified in FIG. 6A, a first LED unit 101A and a second LED unit 101B are fixed on an insulating substrate 19. Similar to the embodiment as shown in FIG. 4A, in the present embodiment, the first electrode 14 is electrically connected with the conductive layer (acting as the second electrode) 17 via a first interconnect 20A, and the third electrode 16 of the first LED unit 101A is electrically connected with the conductive layer 17 of the second LED unit 101B via a second interconnect 20B.

FIG. 6B shows a cross section of another LED device 105 according to the fourth embodiment of the present invention. The present embodiment is similar to FIG. 6A with the exception that a first bonding wire 20C and a second bonding wire 20D are used to replace the first interconnect 20A and the second interconnect 20B, respectively. Specifically, the first bonding wire 20C is used to electrically connect the first electrode 14 and the conductive layer (acting as the second electrode) 17 via a circuit layout layer that is formed between the conductive layer 17 and the insulating substrate 19; and the second bonding wire 20D is used to electrically connect the third electrode 16 of the first LED unit 101A and the conductive layer 17 of the second LED unit 101B via the circuit layout layer 22.

Although specific embodiments have been illustrated and described, it will be appreciated by those skilled in the art that various modifications may be made without departing from the scope of the present invention, which is intended to be limited solely by the appended claims.

What is claimed is:

1. A light-emitting diode (LED) device, comprising:
at least one LED unit, each the LED unit including:
a substrate;
an electrical coupling layer deposited above the substrate, the electrical coupling layer including a group III nitride;
a parallel-connected epitaxial structure deposited above the electrical coupling layer; and
an intermediate layer deposited between the electrical coupling layer and the parallel-connected epitaxial structure.

2. The LED device of claim 1, wherein the electrical coupling layer is n-type doped.

3. The LED device of claim 2, wherein the parallel-connected epitaxial structure comprises:
a first p-type doped layer above the intermediate layer;
a first quantum-well layer above the first p-type doped layer;
an n-type doped layer above the first quantum-well layer;
a second quantum-well layer above the n-type doped layer; and
a second p-type doped layer above the second quantum-well layer;
wherein the intermediate layer causes a voltage drop between the electrical coupling layer and the first p-type doped layer to approach zero volts.

4. The LED device of claim 3, further comprising:
a superlattice structure between the first p-type doped layer and the first quantum-well layer.

5. The LED device of claim 3, further comprising:
a first electrode on an exposed surface of the electrical coupling layer;
a second electrode on a surface of the second p-type doped layer; and
a third electrode on an exposed surface of the n-type doped layer.

6. The LED device of claim 1, wherein the intermediate layer comprises a tunnel layer or an ohmic contact layer.

7. The LED device of claim 5, wherein the at least one LED unit comprises a plurality of LED units and the LED device further comprises:
a first connecting element configured to electrically couple the first electrode and the second electrode of the LED unit; and
a second connecting element configured to electrically couple the third electrode of the LED unit with the first or the second electrode of an adjacent LED unit.

8. The LED device of claim 7, wherein the first connecting element and the second connecting element are independently selected from the group consisting of an interconnect and a bonding wire.

9. An LED device, comprising:
at least one LED unit, each the LED unit including:
a conductive layer;
a parallel-connected epitaxial structure deposited above the conductive layer;
an electrical coupling layer deposited above the parallel-connected epitaxial structure, the electrical coupling layer including a group III nitride; and
an intermediate layer deposited between the parallel-connected epitaxial structure and the electrical coupling layer.

10. The LED device of claim 9, wherein the electrical coupling layer is n-type doped.

11. The LED device of claim 10, wherein the parallel-connected epitaxial structure comprises:
a second p-type doped layer above the conductive layer;
a second quantum-well layer above the second p-type doped layer;
an n-type doped layer above the second quantum-well layer;
a first quantum-well layer above the n-type doped layer; and
a first p-type doped layer above the first quantum-well layer;
wherein the intermediate layer causes a voltage drop between the electrical coupling layer and the first p-type doped layer to approach zero volts.

12. The LED device of claim 11, further comprising:
a superlattice structure between the first p-type doped layer and the first quantum-well layer.

13. The LED device of claim 11, further comprising:
a mirror layer between the conductive layer and the second p-type doped layer.

14. The LED device of claim 11, further comprising:
a first electrode on an exposed surface of the electrical coupling layer; and
a third electrode on an exposed surface of the n-type doped layer.

15. The LED device of claim 9, wherein the intermediate layer comprises a tunnel layer or an ohmic contact layer.

16. The LED device of claim 14, wherein the at least one LED unit comprises a plurality of LED units and the LED device further comprises:
an insulating substrate, on which the plurality of the LED units are fixed;
a first connecting element configured to electrically couple the first electrode and the conductive layer of the LED unit; and
a second connecting element configured to electrically couple the third electrode of the LED unit with the conductive layer of an adjacent LED unit.

17. The LED device of claim 16, wherein the first connecting element and the second connecting element are independently selected from the group consisting of an interconnect and a bonding wire.

18. The LED device of claim 16, further comprising a plurality of circuit layout layers deposited between the insulating substrate and the plurality of LED units respectively.

19. The LED device of claim 18, wherein the first connecting element comprises a first bonding wire that electrically connects the first electrode with the corresponding circuit layout layer; and the second connecting element comprises a second bonding wire that electrically connects the third electrode to the corresponding circuit layout layer of the adjacent LED unit.
